(19) United States
(12) Patent Application Publication
(10) Pub. No.: US 2016/0049458 A1
(43) Pub. Date: Feb. 18, 2016

(54) FISHBONE LC COMPONENT AND METHOD OF MAKING THE SAME

(71) Applicant: QUALCOMM Incorporated, San Diego, CA (US)

(72) Inventors: Young Kyu SONG, San Diego, CA (US); Kyu-Pyung HWANG, San Diego, CA (US)

(21) Appl. No.: 14/459,316

(22) Filed: Aug. 14, 2014

(51) Int. Cl. H01L 49/02

(52) U.S. Cl. CPC H01L 28/10

(57) ABSTRACT

A semiconductor structure according to some examples may include an LC component for use in PMIC applications. The semiconductor structure may have a first conductive coil mounted on an upper surface of a substrate, the first conductive coil surrounding a magnetic core; an output located on a surface of the first conductive coil and coupled to the coil; a dielectric layer located on a surface of the output; and an upper conductive element located on a surface of the dielectric layer, wherein the upper conductive element, the dielectric layer, and the output form a capacitor; and the first conductive coil and the magnetic core form an inductor. The semiconductor structure may also include a second conductive coil located in a same horizontal plane as the first conductive coil, the second conductive coil surrounding a magnetic core where the first conductive coil and the second conductive coil form a fishbone pattern.

### FIELD OF DISCLOSURE

This disclosure relates generally to LC components, and more specifically, but not exclusively, to stacked, fishbone LC components.

### BACKGROUND

Conventionally, power management integrated circuits (power management ICs or PMICs) are integrated circuits (or a system block in a system-on-a-chip device) for managing power requirements of the host system. A PMIC is often included in battery-operated devices such as mobile phones and portable media players. One approach to managing power requirements involves controlling or varying a source power supply. The simplest way to reduce the voltage of a DC supply is to use a linear regulator, but linear regulators waste energy as they operate by dissipating excess power as heat. Buck converters, on the other hand, can be remarkably efficient, making them useful for tasks such as converting the main voltage in a computer (12 V in a desktop, 12-24 V in a laptop) down to the 0.8-1.8 volts needed by the processor. A buck converter is a voltage step down and current step up converter that uses an R-L-C circuit. However, conventional buck converter circuits require a lot of horizontal or board space when implemented on printed circuit boards. Conventional approaches use bulky inductors and capacitors that are placed off-chip for PMICs occupying large board area and often introduce additional resistance and other parasitic elements.

Accordingly, there are long-felt industry needs for methods that improve upon conventional methods including the improved methods and apparatus provided hereby.

The inventive features that are characteristic of the teachings, together with further objects and advantages, are better understood from the detailed description and the accompanying figures. Each of the figures is provided for the purpose of illustration and description only, and does not limit the present teachings.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

Some examples of the disclosure are directed to systems, apparatus, and methods for a stacked, fishbone LC component that achieve a reduced footprint, advantageous high density inductance (up to L ˜200 nH/mm̂2) using magnetic film cored solenoid inductor, and a higher degree of freedom for R, C by connecting multiple LC components in parallel as needed.

In some examples of the disclosure, the system, apparatus, and method includes a semiconductor structure, having a substrate having an upper surface; a first conductive coil mounted on the upper surface of the substrate, the first conductive coil surrounding a first magnetic core; an output located on an upper surface of the first conductive coil and coupled to the first conductive coil; a dielectric layer located on an upper surface of the output; and an upper conductive element located on an upper surface of the dielectric layer, wherein the upper conductive element, the dielectric layer, and the output form a capacitor; and the first conductive coil and the first magnetic core form an inductor. The semiconductor structure may also include a second conductive coil located in a same horizontal plane as the first conductive coil, the second conductive coil surrounding a second magnetic core; wherein the first conductive coil and the second conductive coil form a fishbone pattern.

Other objects and advantages associated with the apparatus and methods disclosed herein will be apparent to those skilled in the art based on the accompanying drawings and detailed description.

### BRIEF DESCRIPTION OF THE DRAWINGS

The accompanying drawings are presented to describe examples of the present teachings, and are not limiting. The accompanying drawings are presented to aid in the description of examples of the disclosure and are provided solely for illustration of the examples and not limitation thereof.

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1A depicts an exemplary step in the formation of a semiconductor structure according to some examples of the disclosure.

FIG. 1B depicts an exemplary step in the formation of a semiconductor structure according to some examples of the disclosure.

FIG. 1C depicts an exemplary step in the formation of a semiconductor structure according to some examples of the disclosure.

FIG. 1D depicts an exemplary step in the formation of a semiconductor structure according to some examples of the disclosure.

FIG. 2A depicts an exemplary step in the formation of a semiconductor structure according to some examples of the disclosure.

FIG. 2B depicts an exemplary step in the formation of a semiconductor structure according to some examples of the disclosure.

FIG. 2C depicts an exemplary step in the formation of a semiconductor structure according to some examples of the disclosure.

FIG. 2D depicts an exemplary step in the formation of a semiconductor structure according to some examples of the disclosure.

FIG. 3A depicts an exemplary step in the formation of a semiconductor structure according to some examples of the disclosure.

FIG. 3B depicts an exemplary step in the formation of a semiconductor structure according to some examples of the disclosure.

FIG. 3C depicts an exemplary step in the formation of a semiconductor structure according to some examples of the disclosure.

FIG. 4 depicts an exemplary exploded view of a LC component according to some examples of the disclosure.

FIG. 5 depicts an exemplary side view of inductive elements of a LC component according to some examples of the disclosure.

FIG. 6 depicts an exemplary diagram of a PMIC with parallel LC components according to some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Methods, apparatus and systems for are provided. The exemplary methods, apparatus, and systems disclosed herein advantageously address the long-felt industry needs, as well as other previously unidentified needs, and mitigate shortcomings of the conventional methods, apparatus, and systems. For example, an advantage provided by the disclosed methods, apparatus, and systems herein is an improvement in.

Various aspects are disclosed in the following description and related drawings to show specific examples of the disclosure. Alternate examples will be apparent to those skilled in the pertinent art upon reading this disclosure, and may be constructed and practiced without departing from the scope or spirit of the disclosure. Additionally, well-known elements will not be described in detail or may be omitted so as to not obscure the relevant details of the aspects and examples disclosed herein.

The word “exemplary” is used herein to mean “serving as an example, instance, or illustration.” Any example described herein as “exemplary” is not necessarily to be construed as preferred or advantageous over other examples. Likewise, the term “examples” does not require that all examples include the discussed feature, advantage or mode of operation. Use of the terms “in one example,” “an example,” “in one feature,” and/or “a feature” in this specification does not necessarily refer to the same feature and/or example. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples only and is not intended to be limiting. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element. Coupling and/or connection between the elements can be physical, logical, or a combination thereof. As employed herein, elements can be “connected” or “coupled” together, for example, by using one or more wires, cables, and/or printed electrical connections, as well as by using electromagnetic energy. The electromagnetic energy can have wavelengths in the radio frequency region, the microwave region and/or the optical (both visible and invisible) region. These are several non-limiting and non-exhaustive examples.

It should be understood that the term “signal” can include any signal such as a data signal, audio signal, video signal, multimedia signal, analog signal, and/or digital signal. Information and signals can be represented using any of a variety of different technologies and techniques. For example, data, an instruction, a process step, a command, information, a signal, a bit, and/or a symbol described in this description can be represented by a voltage, a current, an electromagnetic wave, a magnetic field and/or particle, an optical field and/or particle, and any combination thereof.

Any reference herein to an element using a designation such as “first,” “second,” and so forth does not limit the quantity and/or order of those elements. Rather, these designations are used as a convenient method of distinguishing between two or more elements and/or instances of an element. Thus, a reference to first and second elements does not mean that only two elements can be employed, or that the first element must necessarily precede the second element. Also, unless stated otherwise, a set of elements can comprise one or more elements. In addition, terminology of the form “at least one of: A, B, or C” used in the description or the claims can be interpreted as “A or B or C or any combination of these elements.”

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the examples described herein, the corresponding form of any such examples may be described herein as, for example, “logic configured to” perform the described action.

In this description, certain terminology is used to describe certain features. The term “mobile device” can describe, and is not limited to, a mobile phone, a mobile communication device, a pager, a personal digital assistant, a personal information manager, a mobile hand-held computer, a laptop computer, a wireless device, a wireless modem, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

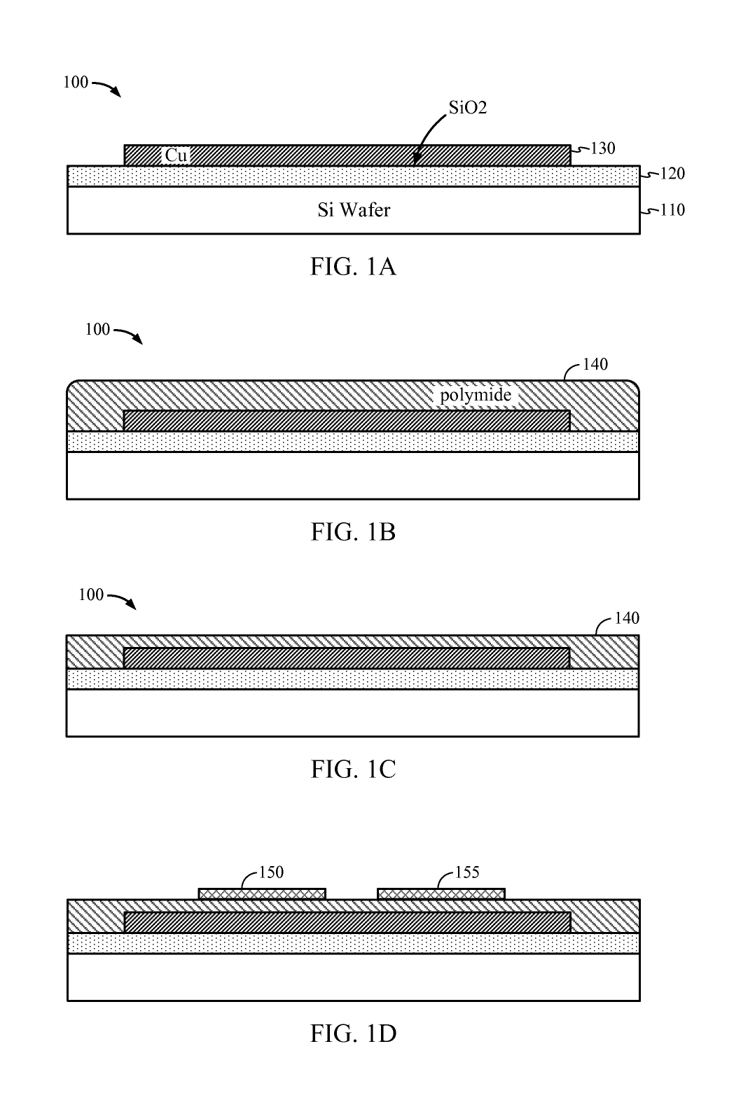

FIG. 1A depicts the beginning steps in the formation of a LC component according to some examples of the disclosure. In FIG. 1A, the LC component 100 may include a substrate 110, a first layer 120 on an upper surface of the substrate 110 and a second layer 130 on an upper surface of the first layer 120 opposite the substrate 110. The substrate 110 is shown as a silicon wafer with a first layer 120 of silicon dioxide and a second layer 130 of copper. However, the various materials depicted can be modified based on the purpose of the specific layer. For example, the copper layer 130 may be some other type of electrically conductive layer to form an interconnection layer that conducts electrical signals. The second layer 130 may be patterned to form part of a fishbone shaped inductive coil along with input and output points or nodes.

FIG. 1B depicts an additional step in the formation of a LC component according to some examples of the disclosure. In FIG. 1B, an insulation layer 140 is added to the LC component 100 to encapsulate the second layer 130. The insulation layer 140 material is shown as a polyimide but other materials may be used as well that have electrical insulation properties but do not interfere with magnetic fields.

FIG. 1C depicts an additional step in the formation of a LC component according to some examples of the disclosure. In FIG. 1C, the insulation layer 140 added to the LC component 100 is reduced but still encapsulates the second layer 130. The insulation layer 140 can be reduced by mechanical, laser, or chemical means depending on the type of material used.

FIG. 1D depicts an additional step in the formation of a LC component according to some examples of the disclosure. In FIG. 1D, a pair of magnetic layers 150 and 155 are added on an upper surface of the insulation layer 140 spaced horizontally from each other. While two magnetic layers are shown, a single magnetic layer or more than two can be formed. The magnetic layers 150 and 155 may be a ferromagnetic, metallic material such as Cobalt Tantalum Zirconium (CoTaZr). The magnetic layers 150 and 155 may be very thin and approximately 2 microns thick in the vertical direction.

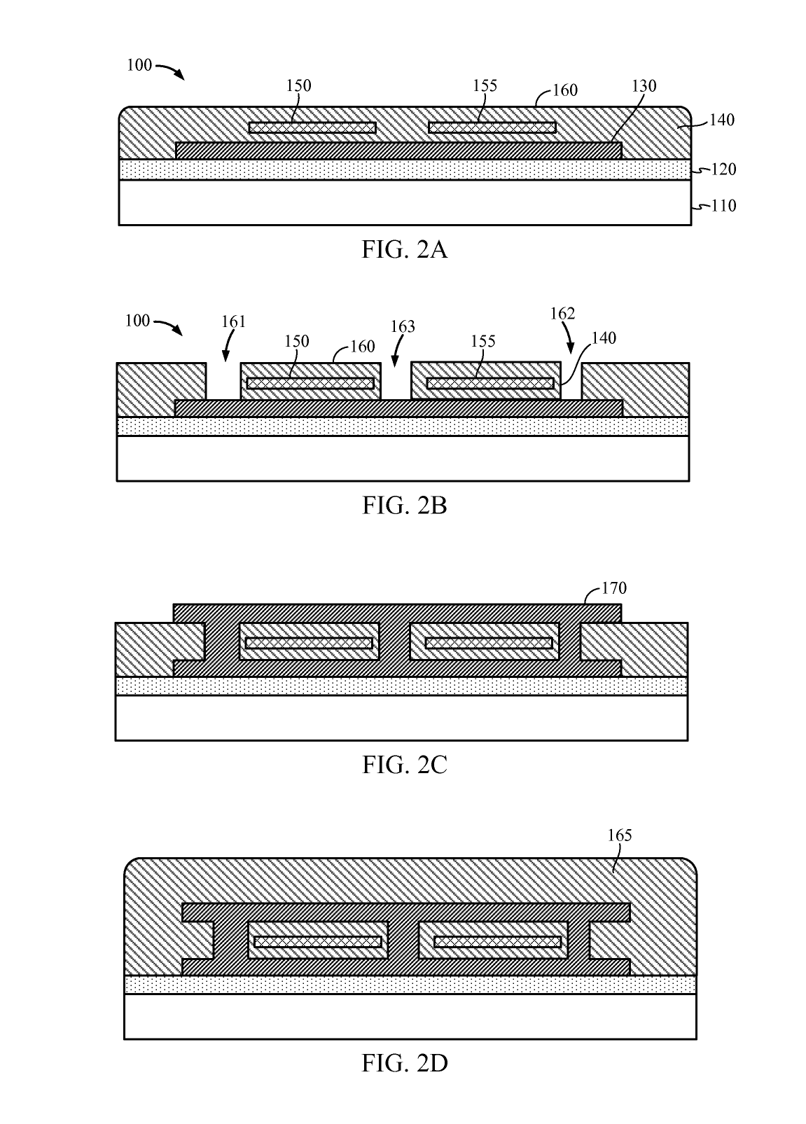

FIG. 2A depicts an additional step in the formation of a LC component according to some examples of the disclosure. In FIG. 2A, a second insulation layer 160 is added to the LC component to encapsulate the second layer 130, first insulation layer 140, and magnetic layers 150 and 155. The second insulation layer 160 material is shown as a polyimide but other materials may be used as well that have electrical insulation properties but do not interfere with magnetic fields.

FIG. 2B depicts an additional step in the formation of a LC component according to some examples of the disclosure. In FIG. 2B, portions 161-163 of the second insulation layer 160 are removed on the sides 161 and 162 of magnetic layers 150 and 155 as well as between 163 layers 150 and 155. The portions 161-163 may be removed by any suitable means such as mechanical, laser, or chemical. The portions 161-163 are removed such that insulation layers 140 and 160 electrically isolate the magnetic layers 150 and 155 from the rest of the LC component 100 while exposing portions of second layer 130.

FIG. 2C depicts an additional step in the formation of a LC component according to some examples of the disclosure. In FIG. 2C, a third layer 170 is added to an upper surface of layer 160 as well as in portions 161-163 of the second insulation layer 160. The third layer 170 may be metallic such as copper and electrically connect the second layer 130 and the third layer 170. The third layer 170 may be patterned in a fishbone shape and connected with similarly patterned second layer 130 to form a pair of conductive coils around magnetic layers 150 and 155 with insulation layers 140 and 160 electrically isolation the layers 150 and 155 from the conductive coils.

FIG. 2D depicts an additional step in the formation of a LC component according to some examples of the disclosure. In FIG. 2D, a third insulation layer 165 is added to the LC component to encapsulate the second layer 130, first insulation layer 140, magnetic layers 150 and 155, and the third layer 170. The third insulation layer 165 material is shown as a polyimide but other materials may be used as well that have electrical insulation properties but do not interfere with magnetic fields.

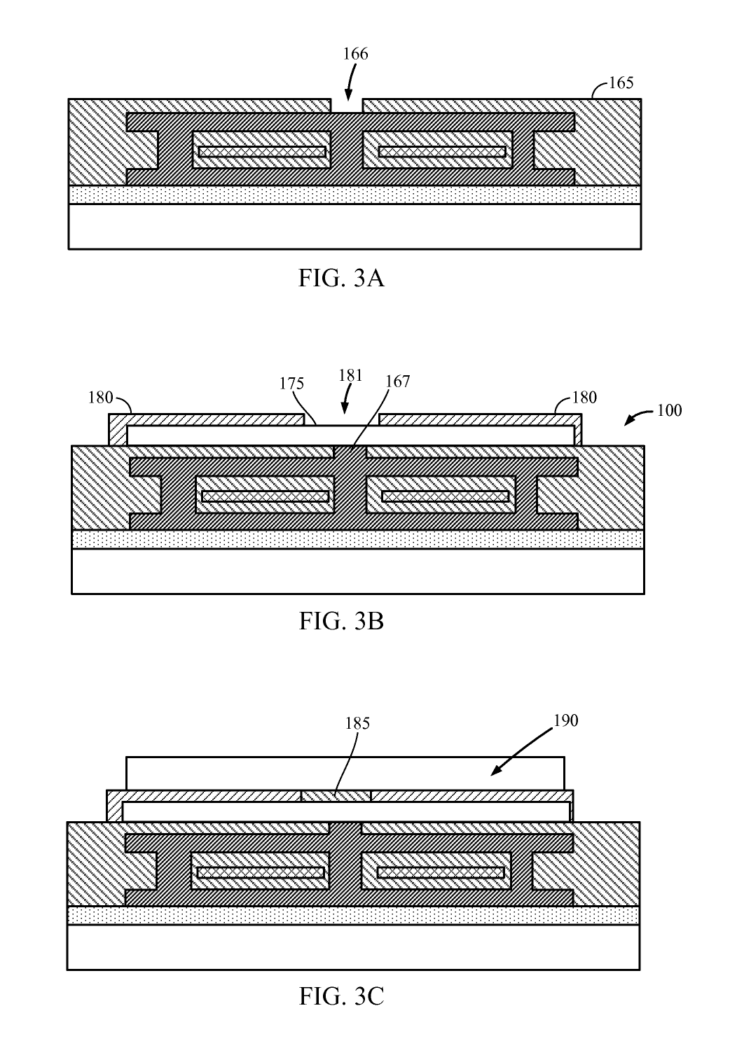

FIG. 3A depicts an additional step in the formation of a LC component according to some examples of the disclosure. In FIG. 3A, the third insulation layer 165 added to the LC component is reduced and a portion 166 is removed to expose a portion of the third layer 170 between the magnetic layers 150 and 155. The insulation layer 165 can be reduced by mechanical, laser, or chemical means depending on the type of material used.

FIG. 3B depicts an additional step in the formation of a LC component according to some examples of the disclosure. In FIG. 3B, a tab 167 is formed in the removed portion 166. The tab 167 may be electrically conductive such as copper and electrically connected to the third layer 170. A fourth layer 175 is added to the surface of the third insulation layer 165 and a dielectric layer 180 is added on a surface of the fourth layer 175 and encapsulates the fourth layer 175. As shown, the dielectric layer 180 includes a gap 181 centered above tab 167. This gap 181 may be formed during the addition of the dielectric layer 180 or by removing a portion of the dielectric layer 180 afterwards. The fourth layer 175 may be metallic such as copper, electrically connected to tab 167, and configured to act as an output for the LC component 100. The dielectric layer 180 may have a high dielectric constant and may be a suitable dielectric material such as aluminum oxide.

FIG. 3C depicts an additional step in the formation of a LC component according to some examples of the disclosure. In FIG. 3C, a fourth insulation layer 185 is added in gap 181 and a fifth layer 190 is added on a surface of the dielectric layer 180 and the fourth insulation layer 185. The fifth layer 190 may be an electrically conductive material such as copper. The fifth layer 190 may be connected to ground and configured to form a ground ring for the LC component 100.

As shown, the fifth layer 190, dielectric layer 180 and fourth layer 175 form a capacitive element or component. In addition, the second layer 130, magnetic layers 150 and 155, and the third layer 170 may form inductive elements with layer 130 and 170 acting as the inductor coils and magnetic layers 150 and 155 acting as magnetic coils for the inductive elements.

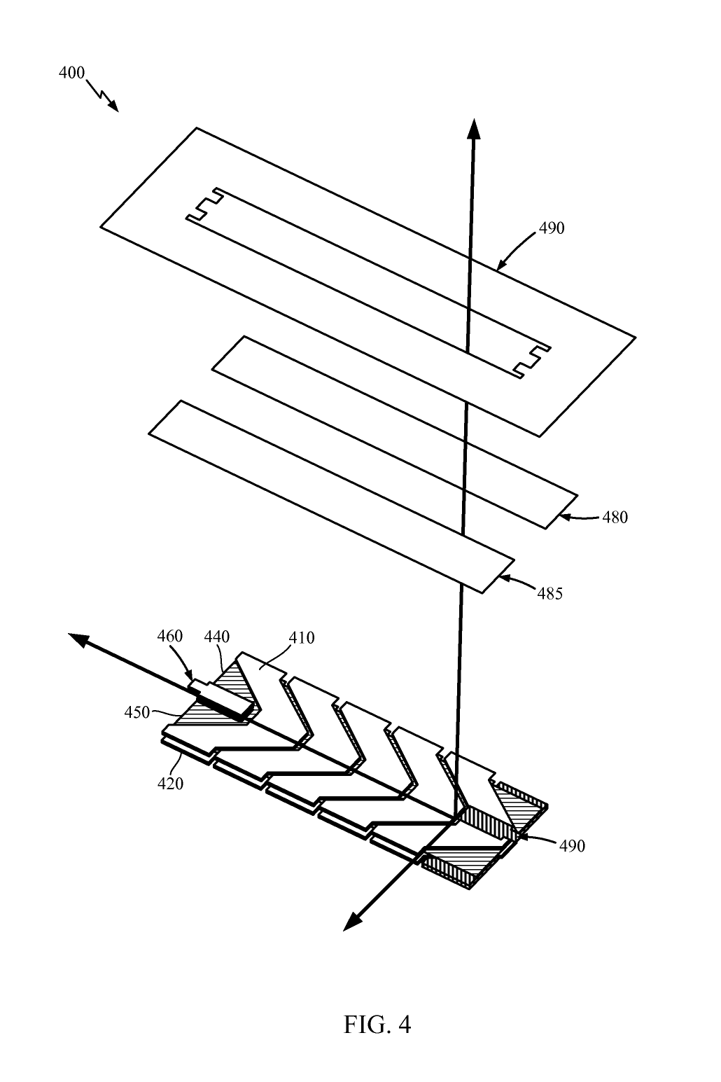

FIG. 4 depicts a LC component according to some examples of the disclosure. In FIG. 4, an LC component 400 may include a pair of conductive coils 410 and 420 forming a fishbone pattern symmetrically about a central axis 430. The conductive coils may surround a pair of magnetic cores 440 and 450. The conductive coil 410 and core 440 form a first inductive element or component and conductive coil 420 and core 450 form a second inductive element or component. The LC component 440 may include an input tab 460 at an edge thereof and along the central axis 430 and may include an output tab 470 at an opposite edge of thereof and along the central axis 430. The LC component may include a pair of conductive output ribbons 480 and 485 and a ground ring 490. The conductive output ribbons 480 and 485 are positioned above the conductive coils 410 and 420 and symmetrical about the central axis 430. The conductive output ribbons 480 and 485 may be coated in a high dielectric material to electrically isolate the ribbons 480 and 485 from the ground ring 490 and the coils 410 and 420. Ribbons 480 and 485 form a pair of capacitive elements with ground ring 490. The LC component 400 may provide an R-L-C type circuit with a DC resistance of 0.11 ohms, an inductance of 12.5 nH at 100 MHz, and a capacitance of 88.9 nF at 100 MHz. The stacked arrangement may provide a smaller footprint for surface mounting then conventional methods and provide greater than 200 nH/mm̂2.

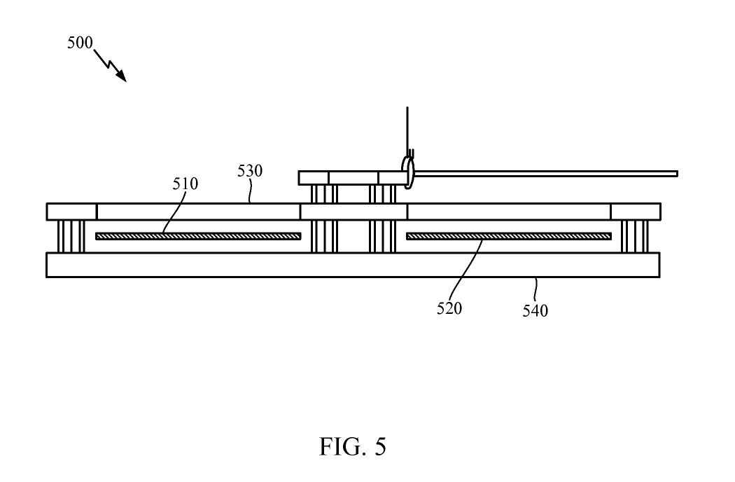

FIG. 5 depicts a twin solenoid inductors LC component according to some examples of the disclosure. In FIG. 5, twin solenoid inductors 500 may include a pair of thin film magnetic cores 510 and 520. The cores 510 and 520 may be approximately 2 microns thick in the vertical direction and composed of ferromagnetic material such as cobalt tantalum zirconium. The cores 510 and 520 are surrounded by solenoid coils 530 and 540.

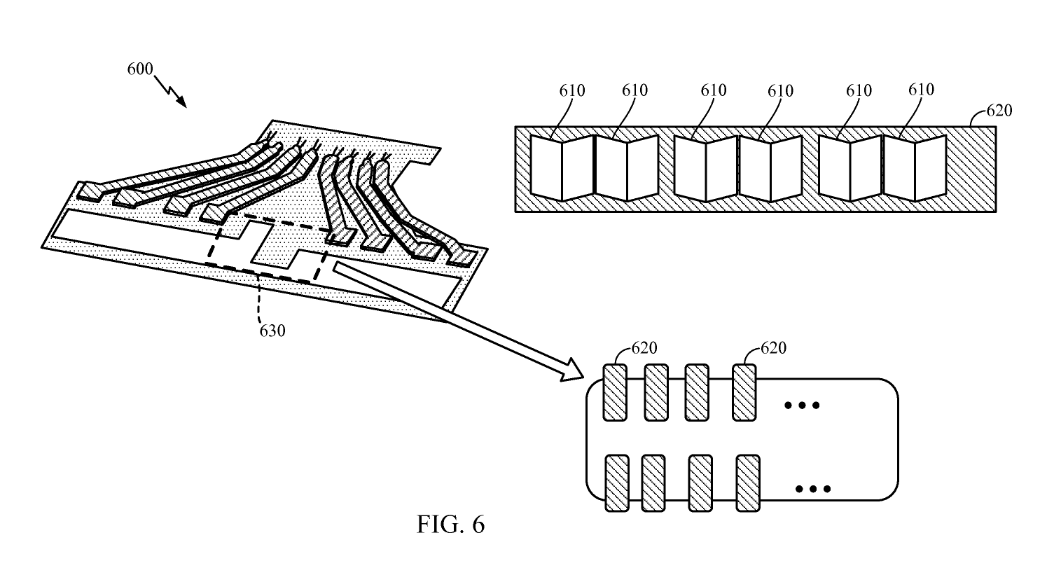

FIG. 6 depicts an exemplary diagram of a PMIC with parallel LC components according to some examples of the disclosure. In FIG. 6, a die side SMT implementation of a PMIC 600 may include a plurality of LC components 610 arranged in parallel to form an LC component block 620. The LC component blocks 620 may be mounted in parallel with other LC component blocks and surface mounted on the PMIC 600 at a suitable location 630 for a multi-terminal SMT implementation of the PMIC 600.

The foregoing description may have references to discrete elements or properties, such as a capacitor, capacitive, a resistor, resistive, an inductor, inductive and the like. However, it will be appreciated that the various aspects disclosed herein are not limited to specific elements and that various components, elements or portions of components or elements may be used to achieve the functionality of one or more or discrete elements or properties. For example, a capacitive component or capacitive element may be a discrete device or may be formed by a specific arrangement of conductive traces separated by a dielectric material or combinations of thereof. Likewise, an inductive component or inductive element may a discrete device or may be formed by a specific arrangement of conductive traces and materials (e.g., air core, magnetic, paramagnetic, etc.) or combinations of thereof. Similarly, a resistive component or resistive element may be a discrete device or may be formed by a semiconductor material, insulating material, adjusting the length and/or cross-sectional area of conductive traces, or combinations of thereof. Moreover, a specific arrangement of conductive traces and materials may provide one or more resistive, capacitive or inductive functions. Accordingly, it will be appreciated that the various components or elements disclosed herein are not limited to the specific aspects and or arrangements detailed, which are provided merely as illustrative examples.

Examples of the methods, apparatus, and systems described herein can be used in a number of applications. For instance, the described examples could be used in mobile phone PMIC, SMT devices, FCBGA, and FCLGA. Further applications should be readily apparent to those of ordinary skill in the art.

Nothing stated or illustrated depicted in this application is intended to dedicate any component, step, feature, object, benefit, advantage, or equivalent to the public, regardless of whether the component, step, feature, object, benefit, advantage, or the equivalent is recited in the claims.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

Although some aspects have been described in connection with a device, it will be appreciated that these aspects also constitute a description of the corresponding method, and so a block or a component of a device should also be understood as a corresponding method step or as a feature of a method step. Analogously thereto, aspects described in connection with or as a method step also constitute a description of a corresponding block or detail or feature of a corresponding device. Some or all of the method steps can be performed by a hardware apparatus (or using a hardware apparatus), such as, for example, a microprocessor, a programmable computer or an electronic circuit. In some examples, some or a plurality of the most important method steps can be performed by such an apparatus.

The examples described above merely constitute an illustration of the principles of the present disclosure. It goes without saying that modifications and variations of the arrangements and details described herein will become apparent to other persons skilled in the art. Therefore, it is intended that the disclosure be restricted only by the scope of protection of the appended patent claims, rather than by the specific details presented on the basis of the description and the explanation of the examples herein.

In the detailed description above it can be seen that different features are grouped together in examples. This manner of disclosure should not be understood as an intention that the examples require more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods disclosed in the description or in the claims can be implemented by a device comprising means for performing the respective steps or actions of this method.

Furthermore, in some examples, an individual step/action can be subdivided into a plurality of sub-steps or contain a plurality of sub-steps. Such sub-steps can be contained in the disclosure of the individual step and be part of the disclosure of the individual step.

While the foregoing disclosure shows illustrative examples of the disclosure, it should be noted that various changes and modifications could be made herein without departing from the scope of the disclosure as defined by the appended claims. The functions, steps and/or actions of the method claims in accordance with the examples of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a substrate having an upper surface;
a first conductive coil mounted on the upper surface of the substrate, the first conductive coil surrounding a first magnetic core;
an output located on an upper surface of the first conductive coil and coupled to the first conductive coil;
a dielectric layer located on an upper surface of the output; and
an upper conductive element located on an upper surface of the dielectric layer,
wherein the upper conductive element, the dielectric layer, and the output form a capacitor; and the first conductive coil and the first magnetic core form an inductor.

2. The semiconductor structure of claim 1, further comprising a second conductive coil located in a same horizontal plane as the first conductive coil, the second conductive coil surrounding a second magnetic core; wherein the first conductive coil and the second conductive coil form a fishbone pattern.

3. The semiconductor structure of claim 1, wherein the semiconductor structure forms a power management integrated circuit.

4. The semiconductor structure of claim 1, wherein the first magnetic core is composed of CoTaZr.

5. The semiconductor structure of claim 4, wherein the first magnetic core is a thin film with a thickness of approximately 2 microns.

6. The semiconductor structure of claim 1, wherein the upper conductive element is a ground ring.

7. The semiconductor structure of claim 1, wherein the semiconductor structure is incorporated into one of a set top box, a music player, a video player, an entertainment unit, a navigation device, a communications device, a personal digital assistant (PDA), a fixed location data unit, or a computer.

8. A semiconductor structure, comprising:
a substrate having an upper surface;
a first inductive component for resisting changes in an electrical current, the first inductive component mounted on the upper surface of the substrate;
a second inductive component for resisting changes in an electrical current, the second inductive component located in a same horizontal plane as the first inductive component, wherein the first inductive component and the second inductive component form a fishbone pattern;
an output located on an upper surface of the first inductive component and second inductive component and coupled to the first inductive component and the second inductive component; and
a capacitive component for electrostatically storing energy, the capacitive component being located on an upper surface of the output.

9. The semiconductor structure of claim 8, wherein the semiconductor structure forms a power management integrated circuit.

10. The semiconductor structure of claim 8, wherein the first inductive component and the second inductive component have a magnetic core composed of CoTaZr.

11. The semiconductor structure of claim 10, wherein the magnetic core is a thin film with a thickness of approximately 2 microns.

12. The semiconductor structure of claim 11, wherein the capacitive component includes a ground ring as a conductive element.

13. The semiconductor structure of claim 8, wherein the semiconductor structure is incorporated into one of a set top box, a music player, a video player, an entertainment unit, a navigation device, a communications device, a personal digital assistant (PDA), a fixed location data unit, or a computer.

14. A method of forming a semiconductor structure, comprising the steps of:
forming a substrate having an upper surface;
forming a first conductive coil mounted on the upper surface of the substrate, the first conductive coil surrounding a first magnetic core;
forming an output located on an upper surface of the first conductive coil and coupled to the first conductive coil;
forming a dielectric layer located on an upper surface of the output; and
forming an upper conductive element located on an upper surface of the dielectric layer,
wherein the upper conductive element, the dielectric layer, and the output form a capacitor; and the first conductive coil and the first magnetic core form an inductor.

15. The method of claim 14, further comprising forming a second conductive coil located in a same horizontal plane as the first conductive coil, the second conductive coil surrounding a second magnetic core; wherein the first conductive coil and the second conductive coil form a fishbone pattern.

16. The method of claim 14, wherein the semiconductor structure forms a power management integrated circuit.

17. The method of claim 14, wherein the first magnetic core is composed of CoTaZr.

18. The method of claim 17, wherein the first magnetic core is a thin film with a thickness of approximately 2 microns.

19. The method of claim 17, wherein the upper conductive element forms a ground ring.

20. The method of claim 14, further comprising incorporating the semiconductor structure into one of a set top box, a music player, a video player, an entertainment unit, a navigation device, a communications device, a personal digital assistant (PDA), a fixed location data unit, or a computer.
